(19) United States
(12) Patent Application Publication
(10) Pub. No.: US 2007/0092635 A1
(43) Pub. Date: Apr. 26, 2007

(54) Apparatus and method for depositing thin films

(76) Inventors: Myung Soo Huh, Suwon-si (KR); Jae Hong Ahn, Suwon-si (KR); Sang Jin Han, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/583,801

(22) Filed: Oct. 20, 2006

(30) Foreign Application Priority Data
Oct. 21, 2005 (KR) 2005-0099909

(51) Int. Cl. B05D 5/06; C23C 16/00

(52) U.S. Cl. 427/64; 427/248.1; 118/726

(57) ABSTRACT

An apparatus and method for depositing a thin film, including a processing chamber having a film forming part and a deposition preventing part, the deposition preventing part being peripheral to the film forming part, an evaporation source in fluid communication with the processing chamber for accommodating a deposition material, and a heat absorbing plate formed in the deposition preventing part of the processing chamber, wherein the heat absorbing plate is positioned to surround a substrate placed in the film forming part of the processing chamber.

### BACKGROUND OF THE INVENTION

1. Field of the Invention

The present invention relates to an apparatus and method for depositing thin films. In particular, the present invention relates to an apparatus and method for depositing thin films capable of maintaining stable temperature and deposition rate, thereby providing improved control of film thickness.

2. Discussion of the Related Art

Deposition of thin films has numerous manufacturing applications. In semiconductor manufacturing, for example, thin films may be deposited in display devices, such as electroluminescent (EL) display devices, to provide photon-emitting mediums to form images. The thin film of the EL display device, for example, may include a plurality of functional layers, e.g., a hole injecting layer, a hole transporting layer, an emission layer, an electron transporting layer, an electron injecting layer, a buffer layer, and/or a carrier blocking layer, that may be arranged in different configurations for achieving a specific function of the EL display device.

Thin films may be applied to a substrate, e.g., an electrode, by methods such as physical vapor deposition (PVD), e.g., vacuum deposition, chemical vapor deposition (CVD), ion plating, sputtering, and so forth. In the vacuum deposition method, for example, a vacuum environment, e.g., vacuum chamber, may be provided with a deposition material, e.g., organic light-emitting material, and a substrate. An evaporation source having a heating unit may be either connected to the vacuum environment or installed therein, such that the operation of the evaporation source may evaporate the deposition material and apply it to a substrate to form a thin film thereon.

However, application of evaporated material onto a substrate may cause non-uniform temperature around the substrate, thereby triggering non-uniform deposition rate and film thickness.

Accordingly, there remains a need for a thin film deposition apparatus and a method employing the same for maintaining stable temperature in order to provide improved control of deposition rate and film thickness.

### SUMMARY OF THE INVENTION

The present invention is therefore directed to an apparatus for depositing thin films and method of producing the same, which substantially overcome one or more of the disadvantages of the related art.

It is therefore a feature of an embodiment of the present invention to provide an apparatus for depositing thin films, the apparatus having the capability of providing improved temperature uniformity inside a processing chamber.

It is another feature of an embodiment of the present invention to provide a method of depositing thin films, the method providing an improved control over temperature and film thickness.

At least one of the above and other features and advantages of the present invention may be realized by providing an apparatus for depositing thin films, including a processing chamber having a film forming part and a deposition preventing part, the deposition preventing part being peripheral to the film forming part, an evaporation source in fluid communication with the processing chamber for accommodating a deposition material, and a heat absorbing plate formed in the deposition preventing part of the processing chamber, wherein the heat absorbing plate is positioned to surround a substrate placed in the film forming part of the processing chamber. The deposition material may be an organic light-emitting deposition material.

The heat absorbing plate may be formed of a ceramic-based material. Alternatively, the heat absorbing plate may include a blacking layer formed thereon between the heat absorbing plate and the evaporation source. The blacking layer may be formed to a thickness ranging from about 10 μm to about 100 μm.

The film forming part may include a mask placed between the substrate and the evaporation source. The apparatus according to an embodiment of the present invention may include a deposition rate measuring unit. Additionally, the apparatus according to an embodiment of the present invention may include a supporting unit for securing the substrate in the film forming part. The processing chamber may be a vacuum chamber.

According to another aspect of the present invention, there is provided a method of depositing thin films, including forming a film forming part and a deposition preventing part in a processing chamber, the deposition preventing part being peripheral to the film forming part, providing an evaporation source having at least one heating unit, at least one nozzle, and a deposition material, placing a substrate in the film forming section, such that a surface of the substrate to be coated is facing the evaporation source, forming a heat absorbing plate in the deposition preventing section, such that the heat absorbing plate surrounds the substrate and absorbs heat generated by the evaporation source heating unit, operating the evaporation source to evaporate the deposition material, and releasing the evaporated deposition material through the evaporation source nozzle onto the substrate to form a film.

Forming of the heat absorbing plate may include forming a blacking layer having a thickness of from about 10 μm to about 100 μm on the heat absorbing plate between the heat absorbing plate and the evaporation source. Forming the blacking layer may include any one of a phosphate coating processing, an igneous material coating processing, and a chromate coating processing.

Operating the evaporation source may include evaporating an organic light-emitting deposition material. Forming a film forming part and a deposition preventing part may further include providing a vacuum environment in the processing chamber. Additionally, the inventive method may include operating a deposition rate measuring unit.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a perspective view of an apparatus for depositing thin films according to an embodiment of the present invention;

FIG. 2 illustrates a sectional view of an apparatus for depositing thin films taken along line I-I′ of FIG. 1;

FIG. 3 illustrates a plan view of a substrate with respect to a heat absorbing plate according to an embodiment of the present invention; and

FIG. 4 illustrates a perspective view of an evaporation source according to an embodiment of the present invention.

### DETAILED DESCRIPTION OF THE INVENTION

Korean Patent Application No. 10-2005-0099909, filed on Oct. 21, 2005, in the Korean Intellectual Property Office, and entitled: “Apparatus for Depositing Thin Film and Method of Depositing Thin Film Using the Same,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and elements may be exaggerated for clarity of illustration. It will also be understood that when a layer or element is referred to as being “on” another layer, element, or substrate, it can be directly on the other layer, element, or substrate, or intervening layers/elements may also be present. Further, it will be understood that when a layer or element is referred to as being “under” another layer or element, it can be directly under, or one or more intervening layers or elements may also be present. In addition, it will also be understood that when a layer or element is referred to as being “between” two layers or elements, it can be the only layer or element between the two layers/elements, or one or more intervening layers or elements may also be present. Like reference numerals refer to like elements throughout.

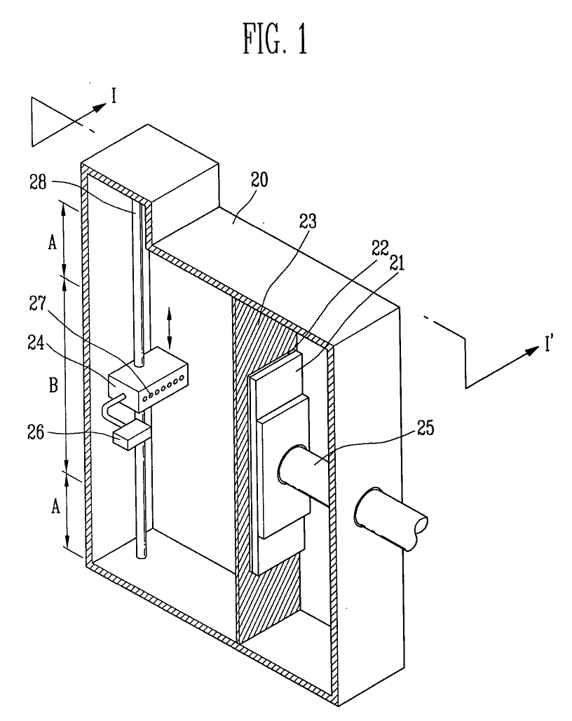

An exemplary embodiment of an apparatus in accordance with the present invention will now be more fully described with reference to FIGS. 1 and 3-4.

As illustrated in FIG. 1, an apparatus for depositing thin films according to an embodiment of the present invention may include a processing chamber 20, an evaporation source 24, and a heat absorbing plate 23.

The processing chamber 20 of an embodiment of the present invention may be any type of vessel known by those skilled in the art for use in film processing, and, preferably, it may be a pressure-controlled vessel such as a vacuum chamber. The processing chamber 20 may be formed to have a deposition preventing part A and a film forming part B.

The film forming part B, as illustrated in FIG. 1, may refer to the central area of processing chamber 20. The central area of processing chamber 20 may correspond to the position where a substrate may be placed and formation of a film, e.g., vacuum deposition processing, may occur. The deposition preventing part A, as illustrated in FIG. 1, may refer to the area inside the processing chamber 20 that surrounds the film forming part B. In other words, the deposition preventing part A may be formed as peripheral portions of film forming part B. The peripheral portions, i.e., deposition preventing part A, may be excluded from film deposition processing.

For example, as illustrated in FIG. 1, a substrate 21 and a mask 22 may be placed in the film forming part B of processing chamber 20. In particular, the substrate 21 may be placed in the center of the processing chamber 20, i.e., film forming part B, facing the evaporation source 24, such that the deposition preventing part A surrounds it. The mask 22 may be attached to the substrate 21 between the substrate 21 and the evaporation source 24. The mask 22 may include a pattern formation unit (not shown) having a pattern corresponding to a pattern to be imparted to a thin film formed on the substrate 21, and a fixation unit (not shown) secured to a mask frame (not shown) through welding.

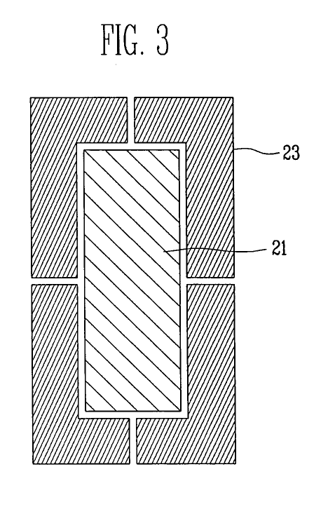

The heat absorbing plate 23 of an embodiment of the present invention may be formed in the deposition preventing part A of the processing chamber 20, as illustrated in FIG. 1. In other words, the heat absorbing plate 23 may be formed only in the peripheral portions of the processing chamber 20, such that the heat absorbing plate 23 may surround the substrate 21 placed in the film forming part B of the processing chamber 20 in order to absorb any potential excess heat radiated from the evaporation source 24 to the substrate 21. In particular, a heat absorbing plate 23 may be divided into four parts, such that the four parts are arranged as a frame around the substrate 21, as shown in FIG. 3.

The heat absorbing plate 23 may be formed of any suitable material known in the art in order to enhance heat absorption. For example, the heat absorbing plate 23 may be formed of a ceramic-based material. Alternatively, the heat absorbing plate 23 may be coated with a blacking layer having a thickness ranging from about 10 μm to about 100 μm. The blacking layer may be formed of any known blacking agent known in the art, e.g., an opaque material, in order to enhance heat absorption of the heat absorbing plate 23.

The evaporation source 24 of an embodiment of the present invention may contain a deposition material for forming a thin film. The deposition material may be any type of material employed in the art for forming thin films in display devices. For example, the deposition material may be a light-emitting material, or, more preferably, an organic light-emitting material.

The evaporation source 24 may provide sufficient heat to vaporize the deposition material therein, and, subsequently, apply it onto the substrate 21. The evaporation source 24 may be formed to have at least one outlet that is in fluid communication with the processing chamber 20, and, preferably, the evaporation source 24 may be formed on a shaft 28 inside a processing chamber 20.

The shaft 28 may be formed parallel to the substrate 21 inside the processing chamber 20, and the shaft 28 may include a rotary unit (not shown) that may rotate and move the evaporation source 24 along the shaft 28. Accordingly, the evaporation source 24 may be a moveable unit that may perform vertical or horizontal film deposition onto the substrate 21.

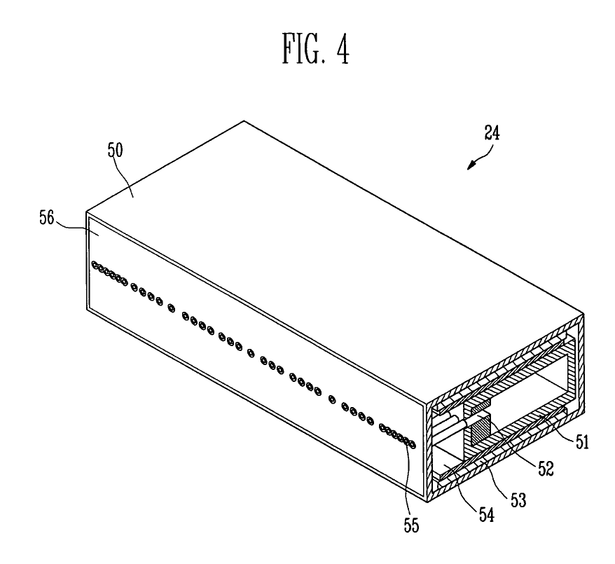

The detailed structure of the evaporation source 24 will be described in more detail with respect to FIG. 4. The evaporation source 24 of an embodiment of the present invention may include a furnace 51 for storing the deposition material, at least one heating unit 54, at lest one reflector 53, an insulating plate 56, at least one spray nozzle 55, and an induction channel 52 for guiding the evaporated deposition material from the furnace 51 to the spray nozzle 55. The evaporation source 24 may also include a housing 50 to enclose all the above components.

The housing 50 may be formed to include a double wall having an internal wall (not shown) and an external wall (not shown). The double wall structure may provide sufficient space therebetween for holding cooling water to facilitate temperature control.

The furnace 51 may contain the deposition material to be deposited onto the substrate 21, and it may be formed of any material known in the art that has excellent heat conductivity. In particular, the furnace 51 may be formed of a ceramic material, e.g., graphite, silicon carbide (SiC), aluminum nitride (AlN), alumina (Al₂O₃), boron nitride (BN), quartz, and so forth, or of a metal, e.g., titanium (Ti), stainless steel, and so forth.

The heating unit 54 may include at least one electrical heater (not shown). Preferably, the evaporation source 24 may include a plurality of heating units 54, each heating unit 54 having at least one electrical heater. As such, the heating units 54 may be formed in close proximity to the furnace 51 to provide sufficient heat to evaporate the deposition material contained therein. Preferably, a heating unit 54 may be formed on each longitudinal side of the furnace 51, as illustrated in FIG. 4.

At least one reflector 53 may be provided between each heating unit 54 and the housing 50 surrounding the furnace 51. Preferably, the evaporation source 24 may include a plurality of reflectors 53 formed in close proximity to the heating units 54 to reflect heat emitted from the heating units 54 into the furnace 51, and, thereby, to minimize heat leakage outside the evaporation source 24.

The spray nozzle 55 may be formed through the housing 50, and it may face the substrate 21. Preferably, the evaporation source 24 may include a plurality of spray nozzles 55.

The insulating plate 56 may be formed between the furnace 51 and a wall of the housing 50 facing the substrate 21, such that heat transfer from the induction channel 52 through the nozzles 55 into the film forming part B of the processing chamber 20 and the substrate 21 may be minimized.

In accordance with an embodiment of the present invention, the apparatus for forming films may also include a deposition rate measuring unit 26 affixed to the evaporation source 24, such that the deposition rate measuring unit 26 and the evaporation source 24 may move jointly along the shaft 28. The deposition rate measuring unit 26 may also be integral to the evaporation source 24. The joint motion of the deposition rate measuring unit 26 and the evaporation source 24, whether integrated or not, may allow continuous real-time measurement of the evaporation rate of the deposition material and control of its deposition rate onto the substrate 21.

The deposition rate measuring unit 26 may also have the capability of adjusting the evaporation rate of the deposition material in order to achieve a specific deposition rate onto the substrate 21. For example, the deposition rate measuring unit 26 may be electrically connected to the heating unit 54 of the evaporation source 24, such that the heat amount generated for evaporating the deposition material in the evaporation source 24 may be increased or decreased with respect to a desired deposition rate. Similarly, the deposition rate measuring unit 26 may be electrically connected to the rotary unit of the shaft 28, such that the speed at which the evaporation source 24 moves along shaft 28 may be increased or decreased with respect to the amount of the evaporated deposition material. The control of the evaporation source 24 speed may facilitate control of the exposure time of the substrate 21 to the evaporation source 24, i.e., deposition rate.

In accordance with an embodiment of the present invention, the apparatus for forming films may further include a supporting unit 25. The supporting unit 25 may be coupled to the processing chamber 20 in order to secure the substrate 21 and the mask 22 in the film forming part A of the processing chamber 20, as illustrated in FIG. 1. The supporting unit 25 may be formed, for example, as a longitudinal member with a flat perpendicular plate attached thereto, i.e., T-shaped, connected to the processing chamber 20 at one end and to the substrate 21 at the other end, such that the substrate 21 may be stably secured in its position. Additionally, an alignment system (not shown) may be added to align the substrate and a mask thereon.

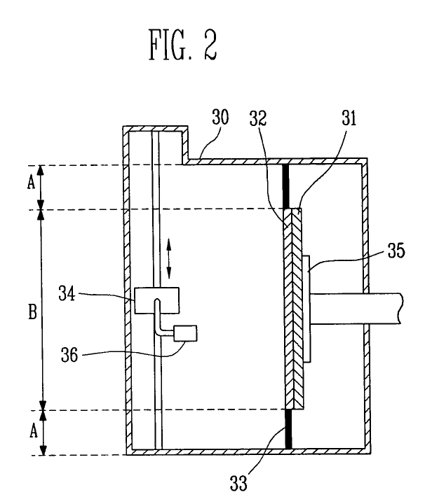

According to another aspect of the present invention, an exemplary method of depositing a thin film onto a substrate is described below with reference to FIG. 2, illustrating a sectional view taken along the line I-I′ of FIG. 1. It should be noted, however, that the particular apparatus elements included in the embodiment illustrated in FIG. 2, as well as their formation, correspond to the exemplary apparatus embodiment previously discussed with respect to FIGS. 1 and 3-4. Accordingly, any detailed discussion of the same elements will not be repeated herein.

A substrate 31 may be placed in a film forming part B of a processing chamber 30, e.g., a vacuum chamber, and secured therein with a supporting unit 35. A mask 32 may be attached to a surface of the substrate 31 to be coated. An evaporation source 34 may be provided into the processing chamber 30, such that the evaporation source 34 may face the surface of the substrate 31 to be coated.

A heat absorbing plate 33 may be formed in the deposition preventing part A of the processing chamber 30 around the substrate 21. In particular, the heat absorbing plate 33 may be formed of a ceramic-based material or it may be coated with a blacking layer, i.e., the surface of the heat absorbing plate 33 may be made black. As such, the heat absorbing plate 33 may absorb the heat in the processing chamber 30 and, thereby, reduce potential excess heat surrounding the substrate 21 and improve its temperature uniformity. Without intending to be bound by theory, it is believed that uniform temperature may provide a uniform deposition rate, e.g., deposition rate no more than about 1.0 angstrom/s, thereby improving control of film thickness.

The formation of the blacking layer may be referred to as a blacking process. In particular, the blacking process may be performed by any method known in the art, such as, for example, phosphate coating, igneous base coating, and chromate coating. For example, in the phosphate coating process, an etchant, i.e., phosphate, may be applied by a chemical or electro-chemical reaction to a metallic layer to form a corrosion product layer, i.e., a phosphate coating film. Alternatively, in the chromate coating process, a solution of chromate or dichromate may be applied to a substrate, i.e., a material to be chromate-coated, to form a chromate coating film.

Once the apparatus and its components are set, a deposition material, e.g., a metal or a light-emitting material such as an organic light-emitting material employed in manufacturing of organic light-emitting diodes (OLEDs), may be placed in the evaporation source 34. Next, the evaporation source 34 may be operated to evaporate, e.g., gasify or sublimate, the deposition material. Preferably, the evaporation temperatures in the evaporation source 34 may be low, i.e., temperatures ranging from about 200° C. to about 400° C.

The evaporated deposition material may be applied to the substrate 31 by any means known in the art, e.g., spraying. During application to the substrate 31, the deposition material may undergo additional continuous processes, e.g., adsorption, deposition, re-evaporation, and so forth. Once the deposition material is successfully applied to the substrate 31, it may solidify to form a thin film.

It should also be noted that evaporation and deposition of the deposition material may occur simultaneously while the evaporation source 34 moves along a shaft. A deposition rate measuring unit 36 may move jointly with the evaporation source 34 to measure and adjust the evaporation rate of the deposition material and its deposition rate onto the substrate 31. Alternatively, an embodiment of a stationary evaporation source and moveable substrate is not excluded from the scope of this invention.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An apparatus for depositing thin films, comprising:
a processing chamber having a film forming part and a deposition preventing part, the deposition preventing part being peripheral to the film forming part;
an evaporation source in fluid communication with the processing chamber for accommodating a deposition material; and
a heat absorbing plate formed in the deposition preventing part of the processing chamber, wherein the heat absorbing plate is positioned to surround a substrate placed in the film forming part of the processing chamber.

2. The apparatus as claimed in claim 1, wherein the heat absorbing plate comprises a blacking layer formed on the heat absorbing plate between the heat absorbing plate and the evaporation source.

3. The apparatus as claimed in claim 2, wherein the blacking layer is formed to a thickness ranging from about 10 μm to about 100 μm.

4. The apparatus as claimed in claim 1, wherein the heat absorbing plate is formed of a ceramic-based material.

5. The apparatus as claimed in claim 1, wherein the deposition material is organic light-emitting material.

6. The apparatus as claimed in claim 1, wherein the film forming part comprises a mask placed between the substrate and the evaporation source outlet.

7. The apparatus as claimed in claim 1, further comprising a deposition rate measuring unit.

8. The apparatus as claimed in claim 1, further comprising a supporting unit for securing the substrate in the film forming part.

9. The apparatus as claimed in claim 1, wherein the processing chamber is a vacuum chamber.

10. A method of depositing thin films, comprising:
forming a film forming part and a deposition preventing part in a processing chamber, the deposition preventing part being peripheral to the film forming part;
providing an evaporation source having at least one heating unit, at least one nozzle, and a deposition material;
placing a substrate in the film forming section, such that a surface of the substrate to be coated is facing the evaporation source;
forming a heat absorbing plate in the deposition preventing section, such that the heat absorbing plate surrounds the substrate and absorbs heat generated by the evaporation source heating unit;
operating the evaporation source to evaporate the deposition material; and
releasing the evaporated deposition material through the evaporation source nozzle onto the substrate to form a film.

11. The method as claimed in claim 10, wherein forming the heat absorbing plate comprises forming a blacking layer having a thickness of from about 10 μm to about 100 μm on the heat absorbing plate between the heat absorbing plate and the evaporation source.

12. The method as claimed in claim 11, wherein forming the blacking layer includes any one of a phosphate coating processing, an igneous material coating processing, and a chromate coating processing.

13. The method as claimed in claim 10, wherein operating the evaporation source comprises evaporating an organic light-emitting material.

14. The method as claimed in claim 10, wherein forming a film forming part and a deposition preventing part further comprises providing a vacuum environment in the processing chamber.

15. The method as claimed in claim 10, further comprising operating a deposition rate measuring unit.
